(19) United States
(12) Patent Application Publication
(10) Pub. No.: US 2006/0264054 A1
(43) Pub. Date: Nov. 23, 2006

(54) Method for etching a trench in a semiconductor substrate

(76) Inventors: Martin Ulrich Gutsche, Dorfen (DE); Thomas Hecht, Dresden (DE); Harald Seidl, Zorneding (DE); Uwe Rudolph, Dresden (DE); Barbara Lorenz, Dresden (DE); Elisabeth Weikmann, Reichersbeuern (DE)

Correspondence Address: SLATER & MATSIL LLP, 17950 PRESTON ROAD, SUITE 1000, DALLAS, TX, 75252, US

(21) Appl. No.: 11/100,325

(22) Filed: Apr. 6, 2005

(51) Int. Cl. H01L 21/465

(52) U.S. Cl. 438/696; 438/700; 438/734

(57) ABSTRACT

The present invention relates to a method for etching a trench in a semiconductor substrate. More specifically, the present invention relates to a method for etching deep trenches such as those having aspect ratios of 30 and higher. According to embodiments of the invention, a method for etching a trench in a semiconductor substrate includes a first etch cycle wherein the trench is etched to a first depth. Thereafter, a protective liner is deposited on at least the upper part of the trench's sidewalls. The protective liner includes inorganic material. During at least one second etch cycle, the trench is etched to its final depth.

### TECHNICAL FIELD

The present invention relates to method for structuring a trench in a semiconductor substrate. More specifically, the present invention relates to a method for etching deep trenches such as those having aspect ratios of 30 and higher.

### BACKGROUND

A method for etching trenches in a semiconductor substrate is described in the published European Patent Application EP 1 420 438. This method uses a plurality of processing cycles comprising plasma etch and deposition periods. During the etch periods the substrate bias power is pulsed. During the deposition periods a protective coating or layer is formed on the sidewalls of the trench. This protective layer protects the sidewalls and stops further etching thereon. Accordingly, just the trench's bottom is mainly etched and a high aspect ratio is obtained.

The known method uses a polymeric coating as protective layer. This coating is deposited “in situ”, i.e., inside the same process chamber where the etch periods take place. In order to obtain the targeted trench's depth as mentioned above, a plurality of plasma etch and deposition periods have to be applied.

### SUMMARY OF THE INVENTION

In one aspect, the present invention provides a method for etching trenches that provides a large aspect ratio and smooth sidewalls. A further aspect of the invention is to provide a method that is easy to carry out.

The method according to the preferred embodiment of the present invention comprises a first etch cycle wherein the trench is etched to a first depth. Thereafter, a protective layer or protective liner comprising an inorganic material is deposited on at least the upper part of the trench's sidewalls. During at least one second etch cycle the trench is etched to its final depth. The terms “protective liner” and “protective layer” are hereinafter used as synonyms.

According to embodiments of the invention, the protective liner consists of inorganic material. Compared to prior art methods that use polymeric layers, the etch selectivity of the inventive protective liner is much larger. Accordingly, the second etch cycle may be carried out for a longer period of time and a larger etch depth is obtained. In consequence, less plasma etch and deposition periods are required to obtain the targeted trench's depth. It is even possible to reach the final depth in just one second etch cycle; in this case there is no need to deposit a second protective liner.

According to a preferred embodiment of the invention, the protective liner is deposited ex situ. This means that the substrate is removed from the etch chamber where the first etch cycle has been carried out. The protective liner is deposited during a separate process, which may be optimized individually; therefore, there is no need to consider process parameters that are necessary or advantageous with regard to the first etch cycle since the etch cycle and the depositing step are split up and totally separated from another.

The substrate's surface should be cleaned before the protective liner is deposited. Removing the etch byproduct from the first etch step improves the quality of the protective liner and maintains or enlarges the orifice of the trench opening. In contrast to prior art methods, such an additional cleaning step is easy to carry out as the substrate is removed from the process chamber thanks to the “ex situ”-process.

To minimize production costs, just two etch cycles should be applied to reach the trench's final depth. As mentioned above, two etch cycles are usually sufficient since an inorganic protective liner is used.

As an example, the protective liner may consist of or comprise an oxide, a nitride or an oxynitride such as a silicon oxide, a silicon nitride or a silicon oxynitride. Preferably however, the protective liner consists of or comprises a byproduct or a material chemically similar to a byproduct that is produced during the second etch cycle. In the latter case the protective liner will resist to the etch chemicals for quite a long period of time.

If, for instance, during the first or during the second etch cycle silicon oxide is produced as a byproduct, the protective liner preferably consists of a PECVD-oxide.

The first-etch cycle may be carried out using a gas mixture containing HBr, NF₃ and O₂.

The second etch cycle may be carried out using the same gas mixture as the first etch cycle (HBr, NF3 and O2).

The second etch cycle may as well be carried out using a gas mixture containing SF₆ and C₄F₈. A so called “BOSCH” process may be applied as described in detail in European Patent Publication EP 0625285 and U.S. Pat. No. 5,501,893, which are incorporated herein by reference.

Alternatively, the second etch cycle may be carried out using a gas mixture containing SF₆ and O₂. Preferably a so-called “Kryo-process” is used as described in detail in “Dussart R. et al., J. Micromech Microeng. 12, p. 190-196, (2004)”, which is incorporated herein by reference.

According to a further preferred embodiment of the invention, the protective liner is a non-conformal layer that covers exclusively the trench's sidewalls and leaves the trench's bottom uncovered. The protective liner may be deposited by a CVD process, a furnace process or a starved ALD (Atomic Layer Deposition) process. Alternatively the protective liner may be deposited by a Silanol-ALD process. Details are described in “Hausmann D. et al., Science, Vol. 298, p. 402-406 (2002)”, which is incorporated herein by reference.

Alternatively, the protective liner can be a conformal layer that covers the trench's sidewalls and the trench's bottom. Accordingly, the protective liner has to be removed from the trench's bottom first before the trench can be etched further down. However, the upper part of the trench's sidewalls should remain covered by the protective liner in order to achieve high aspect ratios while maintaining the sidewall profile from the first etch step.

The removal of the protective liner from the trench's bottom may be carried out during the second etch cycle. Alternatively, the protective liner may be removed from the bottom during an additional etch step that is carried out before the second etch cycle is started. This additional etch step may be carried out “in-situ” or “ex-situ”, meaning in the same etch reactor where the second etch step is carried out, or in a different etch reactor.

### BRIEF DESCRIPTION OF THE DRAWINGS

In order that the manner in which the above-recited and other advantages and objects of the invention are obtained will be readily understood, a more particular description of the invention briefly described above will be rendered by reference to specific embodiments thereof, which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 illustrates a substrate that is etched according to a prior art method;

FIGS. 2-4 illustrate a first embodiment of the inventive method, wherein a non-conformal protective liner is used; and

FIGS. 5-10 illustrate a second embodiment of the inventive method wherein a conformal protective liner is used.

### DETAILED DESCRIPTION OF ILLUSTRATIVE EMBODIMENTS

The preferred embodiments of the present invention will be best understood by reference to the drawings, wherein like parts are designated by like numerals throughout.

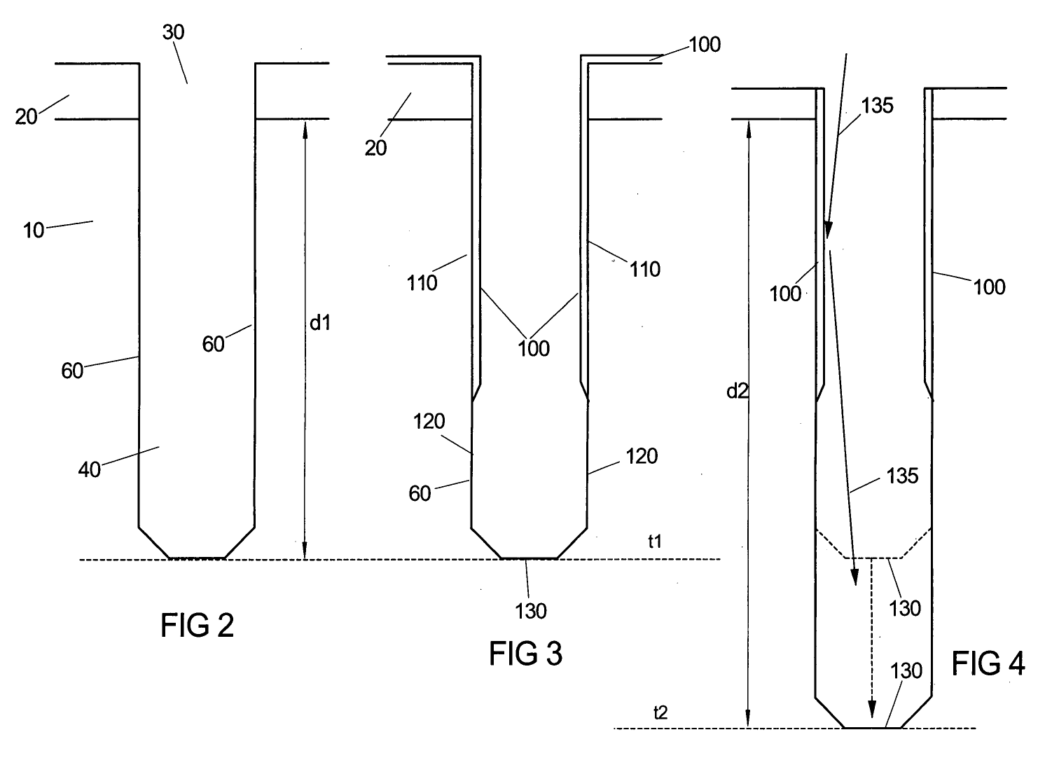

It will be readily understood that the process steps of the present invention, as generally described and illustrated in the figures herein, could vary in a wide range of different process steps. Thus, the following more detailed description of the embodiments of the present invention, as represented in FIGS. 2-10 is not intended to limit the scope of the invention, as claimed, but is merely representative of presently preferred embodiments of the invention.

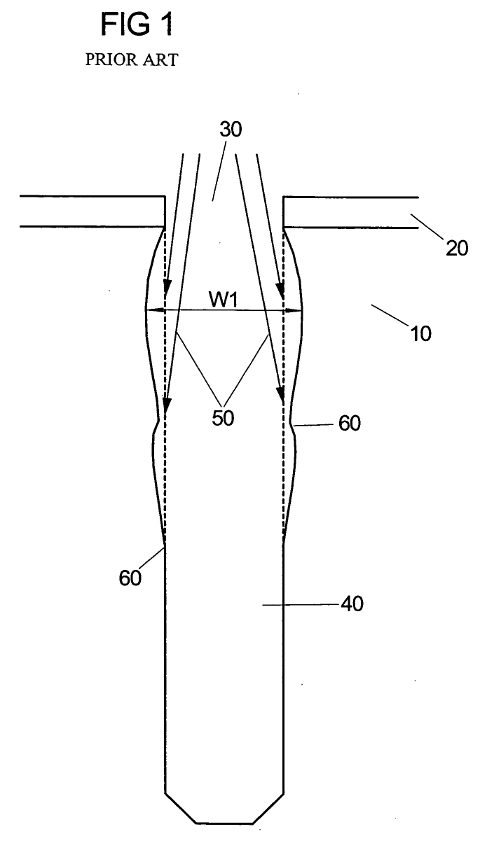

The present invention provides a method for etching a trench in a semiconductor substrate. Referring to FIG. 1, a silicon substrate 10 is illustrated that is etched according to a prior art method. The substrate 10 is covered by structured mask layer 20 providing an opening 30. Through this opening 30, etch chemicals are directed onto the uncovered substrate's surface such that a trench 40 is etched into the substrate 10. The etch chemicals are illustrated by arrows 50. It can be seen in FIG. 1 that the etch chemicals 50 increase the width W1 of the trench 40 such that by lateral etching the formerly vertical sidewalls results in deteriorated sidewalls 60. The lateral deterioration is increasing with increasing trench etch time. Due to this etch behavior the aspect ratio achievable is reduced significantly.

In order to avoid the undesired etch rate in lateral direction and in order to increase the aspect ratio, the invention uses a protective liner at least on the upper part of the trench's sidewalls.

FIGS. 2-4 show a first exemplary embodiment of the inventive method. According to this first embodiment, a non-conformal protective liner is used to avoid lateral etch of the upper portion of the trench while etching high aspect ratios in the later etch steps. This is explained in more detailed hereinafter.

In FIG. 2 a structured mask layer 20 on top of a substrate 10 is illustrated. During a first etch cycle a trench 40 is etched to a first depth d1. For example, the first etch cycle may be carried out using one of the following preferred sets of etch parameters:

| | |
|---|---|
| Parameter set 1: | |
| gas mixture: | HBr, O₂, He—O₂, NF₃, |
| possible gas additives: | SiF₄, HCl, SiCl₄, Ar, SF₆, He |
| pressure range: | 50-200 mT |
| temperature range: | 50-100° C. |
| Parameter set 2: | |
| gas mixture: | SF6, O₂ |
| possible gas additives: | Ar, NF₃, HCl, He-O₂, He |
| pressure range: | 5-300 mT |
| temperature range: | −150-+50° C. |

Then, the substrate 10 is removed from the etch chamber and cleaned. Later on, a protective liner 100 is deposited on the mask layer 20 and on the upper part 110 of the sidewalls 60. The deposition step is handled such that the protective liner 100 is non-conformal; accordingly, the lower part 120 of the sidewalls 60 and the bottom 130 of the trench 40 remain uncovered. For example, the protective liner may be deposited using one of the following preferred sets of deposition parameters; each set of parameters assures that the protective liner is non-conformal and consists of inorganic material:

| | |
|---|---|
| Parameter set 1: | |
| gas mixture: | Trimethylaluminium (Me₃Al), H₂O, O₃ |
| | Tris(tert-butoxy)silanol ((Bu^{t}O)₃SiOH) |
| temperature range: | 150-400° C. |
| Parameter set 2: | |
| gas mixture: | Trimethylaluminium (Me₃Al), H₂O, O₃ |
| pressure range: | 100-500 mT |
| temperature range: | 150-400° C. |
| Parameter set 3: | |
| gas mixture: | TEOS |
| pressure range: | 0.1-0.5 Torr |
| temperature range: | 500-800° C. |

The resulting trench 40 with covered sidewalls 60 is shown in FIG. 3.

After completing the deposition of the protective liner 100 a second etch cycle is applied wherein the trench 40 is etched to its final depth d2. The second etch cycle is shown in FIG. 4. Arrows 135 illustrate that the etch radicals and/or etch ions are reflected by the protective liner 100 in the upper part 110 of the sidewalls 60 and are directed to the bottom 130 of the trench 40. Accordingly, the sidewalls 60 in the upper part 110 will not be etched and a widening of the trench in the upper part is avoided. Instead, the etch radicals and/or etch ions are transferred down to the bottom 130 such that the bottom is mainly etched.

For example, the second etch cycle may be carried out using one of the following preferred sets of etch parameters:

| | |
|---|---|
| Parameter set 1: | |
| gas mixture: | HBr, O₂, He—O₂, NF₃, |
| possible gas additives: | SiF₄, HCl, SiCl₄, Ar, SF₆, He |
| pressure range: | 50-200 mT |
| temperature range: | 50-100° C. |
| Parameter set 2: | |
| gas mixture: | SF₆, O₂ |
| possible gas additives: | Ar, NF₃, HCl, He—O₂, He |
| pressure range: | 3-300 mT |
| temperature range: | −150-+50° C. |
| Parameter set 3: | |
| gas mixture: | SF₆, C₄F₈ |
| possible gas additives: | Ar, NF₃, HCl, O₂, He-O₂ |
| pressure range: | 3-500 mT |
| temperature range: | 0-90° C. |

According to the first exemplary embodiment of the invention, as explained above with reference to FIGS. 2-4, the deposition of the protective liner 100 is carried out ex-situ. This allows to optimize the deposition step of the protective liner 100 independently from both etch cycles.

Preferably, just two etch cycles are used to achieve the targeted etch depth d2 as shown in FIG. 4. Due to the protective liner 100 on the upper part 110 of the sidewalls 60, a high amount of etch ions or etch radicals may be applied during the second etch cycle as the upper part of the sidewalls 110 is protected.

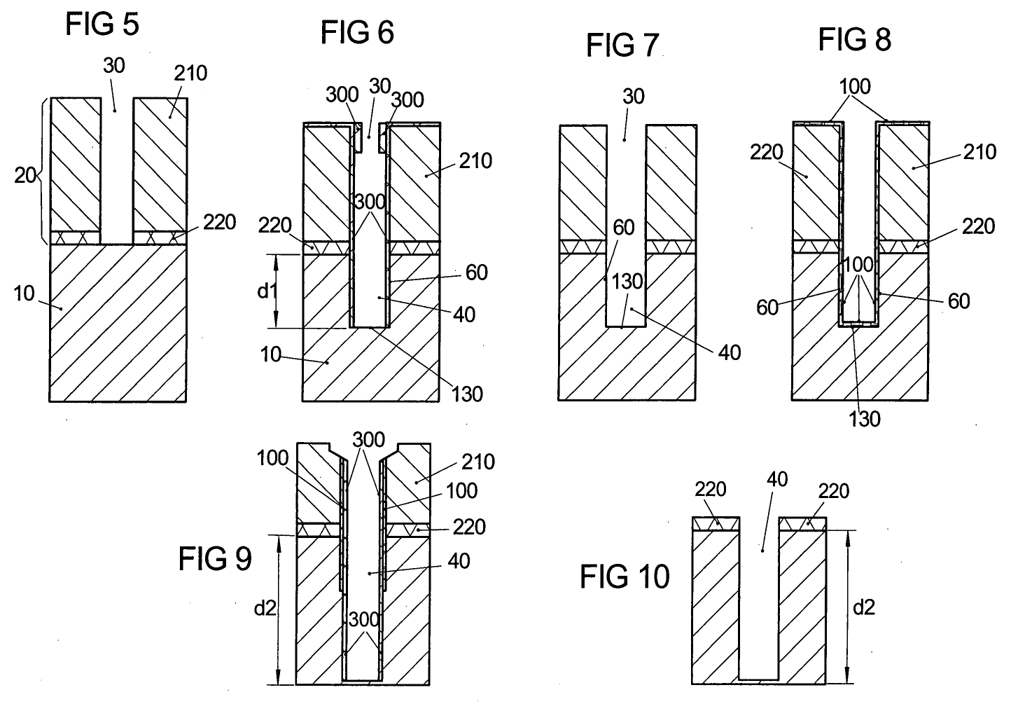

FIGS. 5-10 show a second exemplary embodiment of the inventive method. According to this second embodiment, a conformal protective liner is used to increase the aspect ratio of the trench; this is explained in more detailed hereinafter.

In FIG. 5 a structured mask 20 is sketched consisting of a first mask sub layer 210 and a second mask sub layer 220. The first mask sub layer 210 may consist of oxide material and the second mask sub layer 220 may consist of nitride material.

During a first etch cycle a trench 40 is etched to a first depth d1 into the substrate 10 (see FIG. 6). For example, the first etch cycle may be carried out using one of the following preferred sets of etch parameters:

| | |
|---|---|
| Parameter set 1: | |
| gas mixture: | HBr, O₂, He—O₂, NF₃, |
| possible gas additives: | SiF₄, HCl, SiCl₄, Ar, SF₆, He |
| pressure range: | 50-200 mT |
| temperature range: | 50-100° C. |
| Parameter set 2: | |
| gas mixture: | SF₆, O₂ |
| possible gas additives: | Ar, NF₃, HCl, He—O₂, He |
| pressure range: | 5-300 mT |
| temperature range: | −150-+50° C. |

The following explanations refer explicitly to parameter set 1. As can be seen in FIG. 6, a re-deposition of etch material 300 occurs on the sidewalls 60. As the substrate 10 consists of silicon, the re-deposited etch material 300 comprises a silicon oxide that is contaminated with Bromine. The re-deposited material 300 reduces the size of the mask opening 30; therefore, the first etch cycle is stopped approximately as soon as an etch depth d1 of about 3.5 μm is achieved.

Afterwards, the substrate 10 is cleaned and the re-deposited material 300 is removed. This is done ex-situ, i.e., outside the process chamber where the etch cycle has been carried out. The resulting structure is shown in FIG. 7. The step of cleaning the substrate 100 may include the following steps: wet chemical NH₄OH/H₂O₂ treatment or wet chemical HCl/H₂O₂ treatment or wet chemical diluted HF treatment. Either treatment is followed by a DI-water rinse.

Later on, a protective liner 100 is deposited on the mask layer 20 and on the sidewalls 60. The deposition step is handled such that the protective liner 100 is a conformal layer; the upper part 110 and the lower part 120 of the sidewalls 60 as well as the bottom 130 of trench 40 are covered. For example, the protective liner 100 may be deposited using one of the following preferred sets of deposition parameters; each set of parameters assures that the protective liner 100 is a conformal layer and comprises inorganic material:

| | |
|---|---|
| Parameter set 1: | |
| gas mixture: | O₃ (Ozone) |
| possible gas additives: | O₂, H₂O, Ar, SiH₄, N₂ |
| pressure range: | 10-30 Torr |
| temperature range: | 300-500° C. |
| Parameter set 2: | |
| gas mixture: | TEOS |
| pressure range: | 0.5-5 Torr |
| temperature range: | 500-800° C. |
| Parameter set 3: | |
| gas mixture: | N₂O, NH₃ |
| pressure range: | 1-10 Torr |
| temperature range: | 300-500° C. |
| Parameter set 4: | |
| gas mixture: | SiH₂Cl2, NH₃ |
| pressure range: | 50-300 mT |
| temperature range: | 600-900° C. |

The trench 40 with covered sidewalls 60 is shown in FIG. 8.

After completing the deposition of the protective liner 100 a second etch cycle is applied wherein the trench 40 is etched to its final depth d2. The second etch cycle is shown in FIG. 9. For example, the second etch cycle may be carried out using one of the following preferred sets of etch parameters:

| | |
|---|---|
| Parameter set 1: | |
| gas mixture: | HBr, O₂, He—O₂, NF₃, |
| possible gas additives: | SiF₄, HCl, SiCl₄, Ar, SF₆, He |
| pressure range: | 50-200 mT |
| temperature range: | 50-100° C. |
| Parameter set 2: | |
| gas mixture: | SF₆, O₂ |
| possible gas additives: | Ar, NF₃, HCl, He-O₂, He |
| pressure range: | 3-300 mT |
| temperature range: | −150-+50° C. |
| Parameter set 3: | |
| gas mixture: | SF₆, C₄F₈ |
| possible gas additives: | Ar, NF₃, HCl, O₂, He-O₂ |
| pressure range: | 3-500 mT |
| temperature range: | 0-90° C. |

The following explanations refer explicitly to parameter set 1. As can be seen in FIG. 9, etch material 300 is re-deposited on the sidewalls 60 during the second etch cycle. It can be also seen that the upper mask layer 210 is attacked by the etch gas and finally removed FIG. 10 illustrates the resulting structure.

According to the described second exemplary embodiment of the invention, as explained above, the deposition of the protective liner 100 is carried out ex-situ. This allows to optimize the deposition step of the protective liner independently from both etch cycles.

What is claimed is:

1. A method for etching a trench in a semiconductor substrate, the method comprising:
applying a first etch cycle wherein the trench is etched to a first depth;
depositing a protective liner on at least the upper part of the trench's sidewalls, wherein the protective liner consists of inorganic material; and
applying at least one second etch cycle wherein the trench is etched to a final depth.

2. The method according to claim 1, wherein the protective liner is deposited ex situ.

3. The method according to claim 2, further comprising cleaning a surface of the substrate before the protective liner is deposited.

4. The method according to claim 3, wherein only one second etch cycle is applied to achieve the trench's final depth.

5. The method according to claim 4, wherein the protective liner comprises an oxide, a nitride or an oxynitride.

6. The method according to claim 5, wherein the protective liner comprises silicon oxide, silicon nitride or silicon oxynitride.

7. The method according to claim 4, wherein the protective liner comprises a material that is identical or chemically similar to a byproduct that is produced during the second etch cycle.

8. The method according to claim 7, wherein the first or second etch cycle is carried out such that silicon oxide is produced as a byproduct.

9. The method according to claim 8, wherein the protective liner consists of an PECVD-oxide.

10. The method according to claim 4, wherein the first etch cycle is performed with a first etch selectivity in lateral directions and the second etch cycle is performed with a second etch selectivity in lateral directions, wherein the second etch selectivity is larger than the first etch selectivity.

11. The method according to claim 4, wherein applying the first etch cycle includes applying a HBr/NF₃/O₂ containing gas mixture to the substrate.

12. The method according to claim 4, wherein applying the second etch cycle includes applying a SF₆/C₄F₈ containing gas mixture or a SF₆/O₂ containing gas mixture to the substrate.

13. The method according to claim 4, wherein the protective liner is a non-conformal layer that covers sidewall regions of the trench without covering a bottom of the trench.

14. The method according to claim 4, wherein depositing the protective liner comprises depositing the protective liner by a CVD process or an ALD process.

15. The method according to claim 4, wherein depositing a protective liner comprises depositing a conformal layer that covers the sidewalls of the trench and a bottom of the trench; and
removing the conformal layer from the bottom of the trench such that at least an upper part of the sidewalls remain covered by the conformal layer.

16. The method according to claim 15, wherein the conformal liner is removed from the bottom of the trench before the second etch cycle is started.

17. The method according to claim 15, wherein the protective liner is removed from the bottom of the trench during the second etch cycle.

18. The method according to claim 1, wherein only one second etch cycle is applied to achieve the trench's final depth.

19. The method according to claim 1, wherein the protective liner comprises an oxide, a nitride or an oxynitride.

20. The method according to claim 19, wherein the protective liner comprises silicon oxide, silicon nitride or silicon oxynitride.

21. The method according to claim 1, wherein the protective liner comprises a material being identical or chemically similar to a byproduct that is produced during the first or second etch cycle.

22. The method according to claim 21, wherein the first or second etch cycle is carried out such that silicon oxide is produced as a byproduct.

23. The method according to claim 22, wherein the protective liner consists of a PECVD-oxide.

24. The method according to claim 1, wherein the first etch cycle is performed with a first etch selectivity in lateral directions and the second etch cycle is performed with a second etch selectivity in lateral directions, wherein the second etch selectivity is larger than the first etch selectivity.

25. The method according to claim 1, wherein applying the first etch cycle includes applying a HBr/NF₃/O₂ containing gas mixture to the substrate.

26. The method according to claim 1, wherein applying the second etch cycle includes applying a SF₆/C₄F₈ containing gas mixture or a SF₆/O₂ containing gas mixture to the substrate.

27. The method according to claim 1, wherein depositing the protective liner comprises depositing a non-conformal layer that covers sidewalls of the trench without covering a bottom of the trench.

28. The method according to claim 27, wherein the protective liner is deposited by a CVD process or an ALD process.

29. The method according to claim 1, wherein depositing a protective liner comprises depositing a conformal layer that covers the sidewalls of the trench and a bottom of the trench; and
removing the conformal layer from the bottom of the trench such that at least an upper part of the sidewalls remain covered by the conformal layer.

30. The method according to claim 29, wherein the conformal liner is removed from the bottom of the trench before the second etch cycle is started.

31. The method according to claim 30, wherein the protective liner is removed from the bottom of the trench during the second etch cycle.
